(19) United States
(12) Patent Application Publication
(10) Pub. No.: US 2017/0345796 A1
(43) Pub. Date: Nov. 30, 2017

(54) ELECTRONIC DEVICE WITH STACKED ELECTRONIC CHIPS

(71) Applicant: STMicroelectronics (Grenoble 2) SAS, Grenoble (FR)

(72) Inventor: Eric Saugier, Froges (FR)

(73) Assignee: STMicroelectronics (Grenoble 2) SAS, Grenoble (FR)

(21) Appl. No.: 15/391,211

(22) Filed: Dec. 27, 2016

(30) Foreign Application Priority Data
May 26, 2016 (FR) 1654746

(51) Int. Cl. H01L 25/065; H01L 23/538; H01L 21/822

(52) U.S. Cl. CPC H01L 25/0657; H01L 21/8221; H01L 23/5389

(57) ABSTRACT

An electronic device includes a carrier substrate, a first electronic chip and a second chip. The first chip is mounted on the carrier substrate via interposed electrical connection elements electrically connecting a front electrical connection network of the first chip and an electrical connection network of the carrier substrate. The second chip is mounted on the first chip via interposed electrical connection elements electrically connecting a front electrical connection network of the second chip and a back electrical connection network of the first chip Electrical connection wires electrically connect the back electrical connection network of the first chip to the electrical connection network of the carrier substrate.

### PRIORITY CLAIM

This application claims priority from French Application for Patent No. 1654746 filed May 26, 2016, the disclosure of which is hereby incorporated by reference.

### TECHNICAL FIELD

The present invention relates to the field of electronic devices that include stacked electronic chips.

### BACKGROUND

Electronic devices that include a first electronic chip mounted on top of a carrier substrate and a second electronic chip mounted on top of the first electronic chip have electrical connections made between the second electronic chip and the carrier substrate using electrical connection vias commonly known as through-silicon vias (TSVs) that extend through the first electronic chip.

However, making such through-vias is time consuming, difficult and hence costly, as numerous operations are required, in particular, drilling and thinning of the semiconductive substrate of the first electronic chip are required, in combination with the production, on the front face, of integrated circuits and a layer containing a front electrical connection network.

### SUMMARY

According to the present disclosure, an electronic device includes a carrier substrate that is provided with an electrical connection network; a first electronic chip is provided, on a first side, with integrated circuits and a layer containing a front electrical connection network and a front face. The first electronic chip has, on a second side opposite the first side, a layer containing a back electrical connection network and a back face. A second electronic chip is provided, on a first side, with integrated circuits and a layer containing a front electrical connection network and a front face.

The first chip is mounted on the carrier substrate in a position such that its front face is facing a face of the carrier substrate and via interposed electrical connection elements electrically connecting the front electrical connection network of the first chip and the electrical connection network of the carrier substrate.

The second chip is mounted on the first chip in a position such that its front face is facing the back face of the first chip and via interposed electrical connection elements electrically connecting the front electrical connection network of the second chip and the back electrical connection network of the first chip.

Electrical connection wires electrically connect back pads of the back electrical connection network of the first chip that are arranged on a region of the back face of the first chip that is not covered by the second chip. The pads of the electrical connection network of the carrier substrate are arranged on a region of the carrier substrate that is not covered by the first chip.

Thus, the back electrical connection network of the first chip forms a means for peripherally redistributing the front pads of the second chip, thereby allowing a higher density of electrical connections to be made of the second chip, independently of the internal structure of the first chip.

The region of the carrier substrate that is not covered by the first chip may extend around the entire periphery of the latter.

The region of the first chip that is not covered by the second chip may extend around the entire periphery of the latter.

The electrical connection wires may pass a certain distance away from the periphery of the first chip.

The electrical connection wires are embedded in an encapsulating block.

Outer electrical connection elements may be positioned on the face of the carrier substrate that is opposite the face supporting the first chip. These outer electrical connection elements are electrically connected to the electrical connection network of the carrier substrate.

### BRIEF DESCRIPTION OF THE DRAWINGS

An electronic device will now be described by way of non-limiting exemplary embodiments, with reference to the following FIGURE, wherein:

FIG. 1 is a cross-section of an electronic device that includes stacked electronic chips.

### DETAILED DESCRIPTION

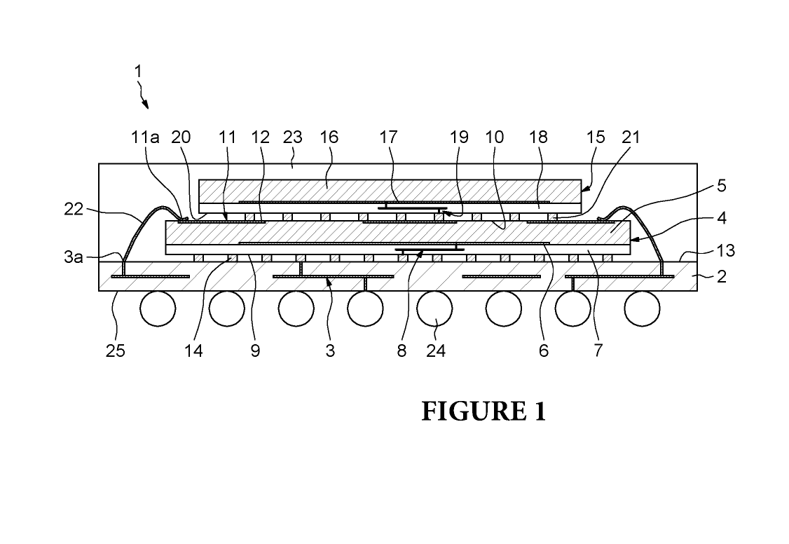

An electronic device 1 is illustrated in FIG. 1 and includes a carrier substrate 2 that is provided with an integrated electrical connection network 3, e.g. a multilayer substrate containing multiple integrated metal electrical connection levels that are electrically connected to one another.

The electronic device 1 includes a first electronic chip 4 provided, on a first side, with a semiconductor substrate 5, integrated circuits 6 and a front layer 7 containing a front electrical connection network 8 and having a front face 9.

The first electronic chip 4 is additionally provided, on a second side opposite the first side, with a layer 10 containing a back electrical connection network 11 and having a back face 12. This back electrical connection network 11 may be produced, for example, in a metal level.

The first chip 4 is mounted on the carrier substrate 2 in a position such that its front face 9 is facing a face 13 of the carrier substrate 2 and is connected thereto via a plurality of interposed electrical connection elements 14. These electrical connection elements 14 connect pads of the electrical connection network 3 of the carrier substrate 2 and front pads of the front electrical connection network 8 of the first chip 4. These electrical connection elements 14 may, for example, comprise metal balls, known to those skilled in the art as “bumping balls” (or “bumps”), or copper pillars.

The electronic device 1 also includes a second electronic chip 15 provided, on a first side, with a semiconductor substrate 16, integrated circuits 17 and a front layer 18 containing a front electrical connection network 19 and having a front face 20.

The second chip 15 is mounted on the first chip 4 in a position such that its front face 20 is facing the back face 12 of the first chip 4 and is connected thereto via a plurality of interposed electrical connection elements 21. These electrical connection elements 21 connect back pads 11a of the back electrical connection network 11 of the first chip 4 and front pads of the front electrical connection network 19 of the second chip 15. These electrical connection elements 21 may, for example, comprise metal balls, known to those skilled in the art as “bumping balls” (or “bumps”), or copper pillars.

The first chip 4 does not cover the entire face 13 of the carrier substrate 2. Advantageously, the first chip 4 leaves a region of the face 13 of the carrier substrate 2 extending around the entire periphery of this first chip 4 uncovered.

The second chip 15 does not cover the entire back face 12 of the first chip 4. Advantageously, the second chip 15 leaves a region of the back face 13 of the first chip 4 extending around the entire periphery of this second chip 15 uncovered, the second chip 15 having a smaller surface area than that of the first chip 4.

The electronic device 1 further includes a plurality of electrical connection wires 22 that pass a certain distance away from the periphery of the first chip 4 and which connect, on the one hand, back pads 11a of the back electrical connection network 11 of the first chip 4, which pads are arranged on that region of the back face 12 of the first chip 4 which is not covered by the second chip 15, and, on the other hand, pads 3a of the electrical connection network 3 of the carrier substrate 2, which pads are arranged on that region of the carrier substrate 2 which is not covered by the first chip 4. The electrical connection wires 22 may be positioned in a row or multiple staggered rows.

It will be noted that the electrical connection network 3 extends below the first chip 4 in order to be connected to the connection elements 14 and extends beyond the periphery of the first chip 4 in said uncovered region in order to be connected to the electrical connection wires 22.

It will also be noted that the back electrical connection network 11 of the first chip 4 extends below the second chip 15 in order to be connected to the connection elements 21 and extends beyond the periphery of the second chip 15 in said uncovered region in order to be connected to the electrical connection wires 22.

Advantageously, the electrical connection wires 22 may be put in place by wire-bonding machines, commonly used in the field of microelectronics, before or after the second chip 15 is put in place.

The electronic device 1 comprises an encapsulating block 23 arranged on the face 13 of the carrier substrate 2 and in which the chips 4 and 15 and the electrical connection wires 22 are embedded, so that the electrical device 1 takes the shape of a parallelepiped.

In one variant embodiment, the encapsulating block 23 may take the form of a bead in which the electrical connection wires 22 are embedded, this bead obstructing the periphery of the space between the carrier substrate 2 and the first chip 4 and the periphery of the space between the first chip 4 and the second chip 15.

The electronic device 1 comprises a plurality of outer electrical connection elements 24, such as metal balls, placed on the face 25 of the carrier substrate 2, opposite its face 13, and connected to the electrical connection network 3. This plurality of outer electrical connection elements 24 is known to those skilled in the art as a “ball grid array” (BGA).

Thus, the electrical connection network 11 and the electrical connection wires 22 may allow the second chip 15 to be electrically connected to the outer electrical connection balls and/or to the first chip 4, for exchanges of signals and/or electrical power.

According to one particular application, the first chip 4 and the second chip 15 may be chips requiring a high interconnect density (the electrical connection elements 14 and 21), this precluding the use of wire bonding via peripheral pads on the front face of the chips. As the second chip 15 is smaller in size than the first chip 4, the back face 12 of the latter may comprise one or more back electrical interconnection levels 11 forming a peripheral fan-out of the electrical connection elements 21 of the second chip 15, allowing the latter to be electrically connected to the first chip 4 and to the substrate 2 via electrical wires and hence at lower cost than with through-silicon vias (TSVs).

According to one variant embodiment, multiple second chips 15 may be mounted on top of the back face 12 of the first chip 4, via respective electrical connection elements 21 that are connected to the back electrical connection network 11 of the first chip 4. Advantageously, the back electrical connection network 11 of the first chip 4 may also be used to electrically connect the plurality of second chips 15 to one another.

What is claimed is:

1. An electronic device, comprising:
a carrier substrate comprising an electrical connection network;
a first electronic chip having integrated circuits and a front layer containing a front electrical connection network and having a front face, and a back layer containing a back electrical connection network and having a back face opposite the front face;
a second electronic chip with integrated circuits and a layer containing a front electrical connection network and having a front face;
wherein the first electronic chip is mounted on the carrier substrate such that the front face of the first electronic chip faces a face of the carrier substrate and is connected thereto via interposed electrical connection elements electrically connecting the front electrical connection network of the first electronic chip to the electrical connection network of the carrier substrate;
wherein the second electronic chip is mounted on the first electronic chip such that the front face of the second electronic chip faces the back face of the first electronic chip and is connected thereto via interposed electrical connection elements electrically connecting the front electrical connection network of the second electronic chip to the back electrical connection network of the first electronic chip; and
electrical connection wires electrically connecting back pads of the back electrical connection network of the first electronic chip to pads of the electrical connection network of the carrier substrate, said back pads being arranged on a region of the back face of the first electronic chip that is not covered by the second electronic chip, said back pads being arranged on a region of the carrier substrate that is not covered by the first electronic chip.

2. The electronic device according to claim 1, wherein said region of the carrier substrate that is not covered by the first electronic chip extends around a periphery of the first electronic chip.

3. The electronic device according to claim 1, wherein said region of the first electronic chip that is not covered by the second electronic chip extends around a periphery of the second electronic chip.

4. The electronic device according to claim 1, wherein the electrical connection wires pass a distance away from a periphery of the first electronic chip.

5. The electronic device according to claim 1, further comprising an encapsulating block in which the electrical connection wires are embedded.

6. The electronic device according to claim 1, further comprising outer electrical connection elements disposed on an outer face of the carrier substrate, the outer face disposed opposite the face facing the first electronic chip, the outer electrical connection elements being electrically connected to the electrical connection network of the carrier substrate.

7. The electronic device according to claim 1, wherein the first electronic chip and the second electronic chip each comprises a semiconductor substrate.

8. The electronic device according to claim 1, wherein the interposed electrical connection elements are either metal balls or copper pillars.

9. An electronic device, comprising:
a carrier substrate defining a central region and a peripheral region and supporting an electrical connection network;
a first integrated circuit chip defining a central region and a peripheral region surrounding the central region, the first integrated circuit chip supported by the central region of the carrier substrate and having a front face disposed facing the carrier substrate and having a front electrical connection network, the front electrical connection network of the first integrated circuit chip being electrically connected to the electrical connection network of the carrier substrate, the first integrated circuit chip further having a back face and a back electrical connection network;
a second integrated circuit chip supported by the central region of the first integrated circuit chip and having a front face disposed facing the back face of the first integrated circuit chip and having a front electrical connection network, the front electrical connection network of the second integrated circuit chip being electrically connected to the back electrical connection network of the first integrated circuit chip; and
electrical connection wires extending from the peripheral region of the carrier substrate to the back electrical connection network of the first integrated circuit chip and electrically connecting the back electrical connection network of the first integrated circuit chip to the electrical connection network of the carrier substrate.

10. The electronic device according to claim 9, wherein the first and the second integrated circuit chips each comprises a semiconductor substrate.

11. The electronic device according to claim 9, wherein the front electrical connection network of the first integrated circuit chip is electrically connected to the electrical connection network of the carrier substrate by metal balls or copper pillars.

12. The electronic device according to claim 11, wherein the front electrical connection network of the second integrated circuit chip is electrically connected to the back electrical connection network of the first integrated circuit chip by metal balls or copper pillars.

13. The electronic device according to claim 9, wherein the peripheral region of the carrier substrate extends around the first integrated circuit chip.

14. The electronic device according to claim 13, wherein the peripheral region of the first integrated circuit chip extends around the second integrated circuit chip.

15. The electronic device according to claim 9, wherein the electrical connection wires are disposed in a row surrounding the first integrated circuit chip.

16. The electronic device according to claim 9, further comprising an encapsulating block embedding the electrical connection wires.

17. The electronic device according to claim 9, further comprising outer electrical connection elements disposed on an outer face of the carrier substrate, the outer face disposed opposite a face facing the first chip, the outer electrical connection elements being electrically connected to the electrical connection network of the carrier substrate.

18. An electronic device, comprising:
a carrier substrate defining a central region and supporting an electrical connection network;
a first integrated circuit chip defining a central region and being supported by the central region of the carrier substrate, the first integrated circuit chip having a front face disposed facing the carrier substrate and having a front electrical connection network, the front electrical connection network of the first integrated circuit chip being electrically connected to the electrical connection network of the carrier substrate, the first integrated circuit chip having a back face and a back electrical connection network;
a second integrated circuit chip supported by the central region of the first integrated circuit chip and having a front face disposed facing the back face of the first integrated circuit chip and having a front electrical connection network, the front electrical connection network of the second integrated circuit chip being electrically connected to the back electrical connection network of the first integrated circuit chip; and
electrical connection wires extending from a region of the carrier substrate beyond the central region of the carrier substrate to electrically connect the electrical connection network of the carrier substrate to the back electrical connection network of the first integrated circuit chip.

19. The electronic device according to claim 18, wherein the region of the carrier substrate beyond the central region of the carrier substrate extends around a periphery of the first integrated circuit chip.

20. The electronic device according to claim 19, wherein the electrical connection wires are connected to pads surrounding a periphery of the second integrated circuit chip.
